(19) United States
(12) Patent Application Publication
(10) Pub. No.: US 2013/0003274 A1
(43) Pub. Date: Jan. 3, 2013

(54) Solar Panel Racking System With Integrated Grounding Bar Rail

(75) Inventors: Carl L. Turziano, Suffern, NY (US); Richard C. Contrata, JR., Harrison, NY (US)

(73) Assignee: ATLANTECH SOLAR INC., Suffern, NY (US)

(21) Appl. No.: 13/614,934

(22) Filed: Sep. 13, 2012

Related U.S. Application Data
(63) Continuation-in-part of application No. 13/399,073, filed on Feb. 17, 2012.
(60) Provisional application No. 61/567,835, filed on Dec. 7, 2011.
(60) Provisional application No. 61/443,798, filed on Feb. 17, 2011.

(51) Int. Cl. H05K 7/18; H05K 13/00

(52) U.S. Cl. 361/679.01; 29/825

(57) ABSTRACT

A photovoltaic panel racking system with integrated grounding bars integrated with an extruded integrated rail. The integrated grounding bar enables grounding of photovoltaic panels to a racking system without the use of additional parts or tools. When photovoltaic panels are installed onto an integrated rail, the grounding bars perforate the anodized coating of the frame of the photovoltaic panels to make metal to metal contacts. The grounding bar may be attached to the underside of solar panel frames. Further, an integrated grounding bar rail reduces the number of roof penetration connections necessary for safe grounding of a photovoltaic system. In a ballast mounted photovoltaic panel system, ballast pans may be used to connect the integrated rails between adjacent rows of photovoltaic panels, thereby further reducing the number of grounding points needed to ground the system.

### CROSS-REFERENCE TO RELATED APPLICATIONS

This application is a continuation-in-part of U.S. patent application Ser. No. 13/399,073 entitled “Solar Panel Racking System With Integrated Grounding Bar Rail” filed on Feb. 17, 2012, which claims the benefit of U.S. Provisional Patent Application Ser. No. 61/443,798, filed on Feb. 17, 2011, and U.S. Provisional Patent Application Ser. No. 61/567,835, filed on Dec. 7, 2011, all of which are assigned to the assignee hereof and are hereby incorporated by reference in their entirety.

### FIELD OF THE INVENTION

The various embodiments relate generally to photovoltaic solar panels and more particularly to efficiently grounding solar panel arrays.

### BACKGROUND

In general, photovoltaic panel frames are anodized to help protect the frames from exposure to the elements. Mounting rails are used to attach photovoltaic panel frames to racking systems. The tops of the mounting rails are generally made of flat, smooth aluminum. The surfaces of the mounting rails are generally anodized, although mill finishes are used on some manufacturer's products. The anodized coating on a solar panel frame helps to minimize the corrosion due to weather. However, the anodized coating also presents a barrier that reduces the effectiveness of the grounding connection.

Under the National Electric Code (NEC), all photovoltaic panel frames are required to be grounded to the racking systems. Grounding may be accomplished by either grounding each individual panel, or by making a contact point of exposed metal between the panels and the rails to create a safe electrical ground. The present technology on the market to create such an exposed metal contact point is the use of grounding clips.

A grounding clip consists of a piece of metal with sharp extruded burrs on both sides. The extruded burrs pierce the anodized coating on panels and rails when tightened by nuts and bolts at the points where the panels are secured to the rails. An example Industry standard product using this technology is the grounding clip produced by WEEB® brand, although other manufacturers in photovoltaic equipment produce various other grounding clips that serve the same purpose. Such grounding clips are separate components from photovoltaic panels and rails.

### SUMMARY

The various embodiments illustrated herein provide devices and methods for grounding photovoltaic solar and building integrated photovoltaic panel (BIPV) power systems without the use of additional parts. The various embodiments provide a solar panel racking system with an integrated grounding bar rail. The integrated grounding bar rail of the various embodiments enables grounding of photovoltaic solar and BIPV panels to the racking system. Further, an integrated grounding bar rail according to the various embodiments may be adaptable to use with all framed solar panel brands and sizes and major solar racking system products, for example, BIPV systems, pole-mounted photovoltaic systems, etc. The integrated grounding bar rail may incorporate “screw bosses” on the top and face of the rail to accommodate not only slide-in bolts, but also self-tapping screws. Furthermore, the integrated grounding bar technology may also be adapted for use on the underside of solar panel frames to achieve proper grounding to the rails.

### BRIEF DESCRIPTION OF THE DRAWINGS

The accompanying drawings, which are incorporated herein and constitute part of this specification, illustrate exemplary aspects of the invention. Together with the general description given above and the detailed description given below, the drawings serve to explain features of the invention.

FIG. 1 is a side plan view of an integrated grounding bar rail and roof mounting system, according to the various embodiments.

FIG. 2 is a side plan view of an extruded rail with two grounding bars, according to an embodiment.

FIG. 3A is a side plan view of an integrated grounding bar on one side of a rail, according to an embodiment.

FIG. 3B is a top elevation view of an integrated grounding bar rail, according to an embodiment.

FIG. 4 is a side plan view of an extruded rail with four grounding bars, according to an embodiment.

FIG. 5 is an exploded side plan view of a slide-in bolt slot and screw boss in an embodiment integrated grounding bar rail.

FIG. 6 is a side plan view of a roof-penetrating rail mounting bracket, according to an embodiment.

FIG. 7 is a side elevation view of a ballast frame for mounting a solar panel racking system, according to an embodiment.

FIG. 8A is a side plan view of a ballast pan in a ballast mounted solar panel system, according to an embodiment.

FIG. 8B is an exploded side plan view of a ballast mounted solar panel system with ballast pans, according to an embodiment.

FIG. 9 is a top elevation view of a ballast mounted system that is grounded through ballast pans and integrated grounding bar rail, according to an embodiment.

FIG. 10 is a front plan view of a ballast pan configured with mounting holes, according to an embodiment.

FIG. 11 is a front plan view of a canopy solar panel racking system, according to an embodiment.

FIG. 12 is a front plan view of a pole mounted solar panel racking system, according to an embodiment.

FIG. 13 is a plan view of a solar panel frame with integrated grounding bars, according to an embodiment.

### DETAILED DESCRIPTION

The various embodiments will be described in detail with reference to the accompanying drawings. Wherever possible, the same reference numbers will be used throughout the drawings to refer to the same or like parts. References made to particular examples and implementations are for illustrative purposes and are not intended to limit the scope of the invention or the claims.

The word “exemplary” is used herein to mean “serving as an example, instance, or illustration.” Any implementation described herein as “exemplary” is not necessarily to be construed as preferred or advantageous over other implementations.

The term “photovoltaic panel” as used herein means a solar panel that can be used to convert light into energy.

The term “ballast mounted system” as used herein means a photovoltaic panel racking system in which a mounting rack is held on top of a surface (e.g., a roof) by weights, as opposed to secured by fastening to a structure itself (i.e., penetrating a roof). Ballast mounted systems may be positioned on other surfaces, for example, on the ground. Concrete blocks are commonly used as ballasts in such a system. Alternatively, ballasts may be made of materials including, but not limited to, sand, water, metal, etc.

The various embodiments illustrated herein relate to a passive device designed to be used specifically during photovoltaic solar panel and BIPV installation. Mounting rails are used to attach the solar panels to a racking system, and are configured with integrated grounding bars comprising sharp, triangle-shaped extruded bars and/or cone shaped prongs, or other forms of sharp serrations running the entire length of the top surface of the rail. These contact the bottom of the anodized aluminum frame of a solar panel. When pressure is applied during mounting process, the grounding bar perforates the anodized coating of solar panel frames, thereby grounding the solar panels to the racking system.

The term “photovoltaic system” as used herein means a system with one or more photovoltaic panels, mechanical and electrical connections, and mountings, which generates and supplies electricity in commercial and residential applications.

The various embodiments provide a mounting rail for a photovoltaic system with one or more integrated grounding bars. When photovoltaic panels are installed onto mounting rails, the integrated grounding bar on the rails may perforate the anodized coating of the panel frames. Mounting clamps, standard with installation of any photovoltaic panel racking system, may be used to tighten the connection between the panel frames and the mounting rails and create a safe ground. Once the panels are grounded to the rails by these metal-to-metal contacts, a continuous ground wire may be run to each rail, connecting to the ends of the rails. In a preferred embodiment, the mounting rail may be configured to span long distances between mounting brackets, thereby minimizing the number of mounting brackets and reducing the number of roof penetrations necessary.

Further, the various embodiments employ ballast pans to hold ballast blocks to anchor a row of photovoltaic panels to a surface. Advantageously, a ballast pan may also function as a grounding conductor to an adjacent row of photovoltaic panels in a preferred embodiment. Thus, the ballast pans serve a dual function of anchoring the photovoltaic system and facilitating electrical grounding, and therefore safety of the system.

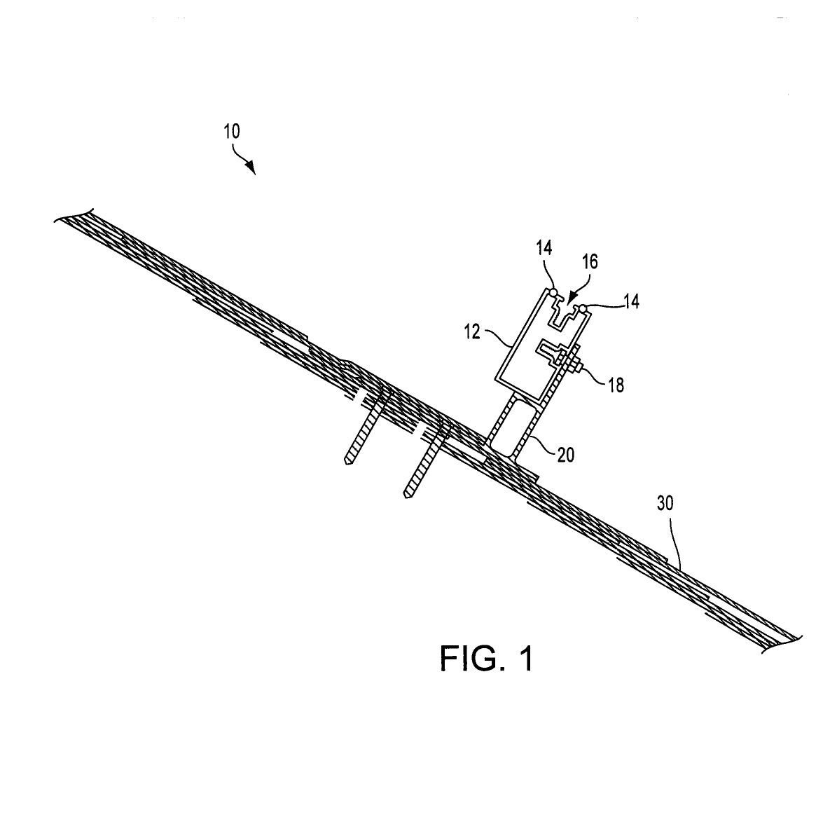

FIG. 1 illustrates a photovoltaic panel racking system 10 according to an embodiment. In the racking system 10, an extruded rail 12, used to attach the photovoltaic panels, may be configured with at least one grounding bar 14 running its length. The rail 12 may be, for example, an aluminum rail. In an exemplary embodiment, the rail 12 may have a top attachment slot 16 and a side attachment slot 18 to secure the rail 12 to mounting brackets 20 and/or secure the photovoltaic panels. Attachment slots may be, for example, slide-in bolt slots, screw bosses, etc. The rail mounting brackets 20 may be configured to hold the rail 12 and may be screwed into the roof underneath shingles. In addition, the racking system according to an embodiment may enable an integrated wire management system. Specifically, the rail 12 may provide a pathway where installation wiring can be run within the perimeter of the rail and eliminate the use of conduit piping.

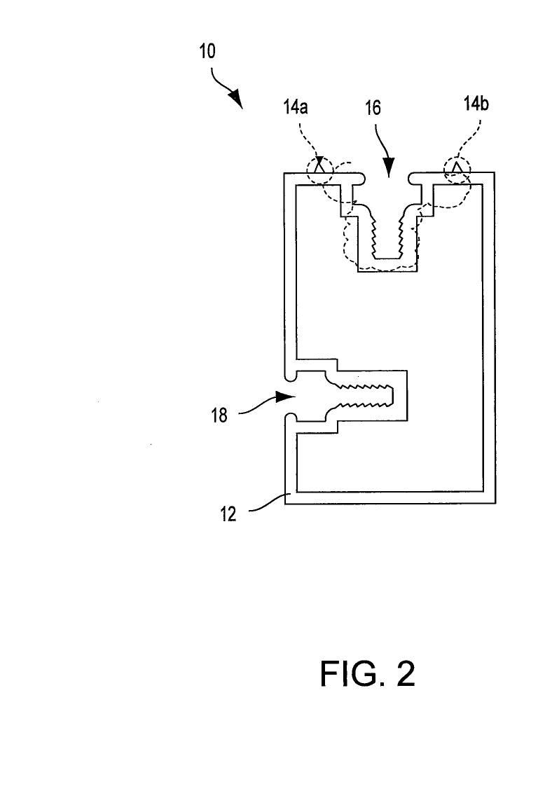

FIG. 2 illustrates rail 12 in the racking system 10, with two grounding bars 14a, 14b and attachment slots 16, 18 on the top and side of the rail 12, respectively.

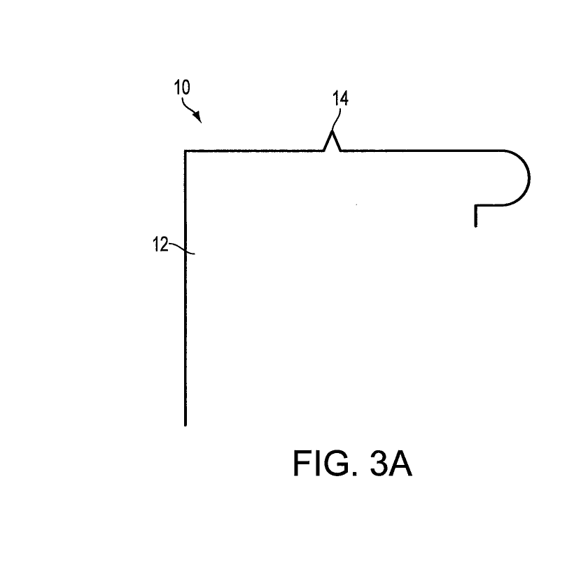

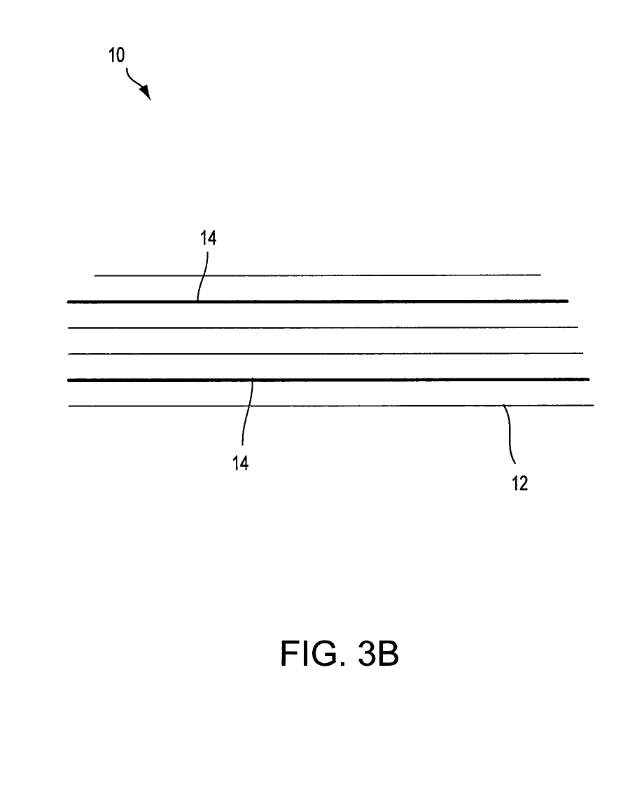

FIG. 3A illustrates in detail embodiment grounding bars 14a, 14b integrated at the top of rail 12 in racking system 10. In a preferred embodiment, the cross section of grounding bar 14 is triangular in shape to enable perforation of photovoltaic panel frames. In an exemplary embodiment, grounding bars 14a, 14b may be sharp extrusions on rails 12. FIG. 3B illustrates the relative locations of the grounding bars 14 and the rail 12.

In an alternative embodiment, grounding bars 14a, 14b may be configured as cone-shaped grounding prongs, or serrations running the entire length of the top surface of the rail. As will be understood by one of ordinary skill in the art, grounding bars may take on other shapes, provided that when the rail contacts the bottom of the anodized aluminum frame and pressure applied during mounting, the grounding rail is sufficiently sharp to perforate the anodized coating of the frame, thereby grounding the panel.

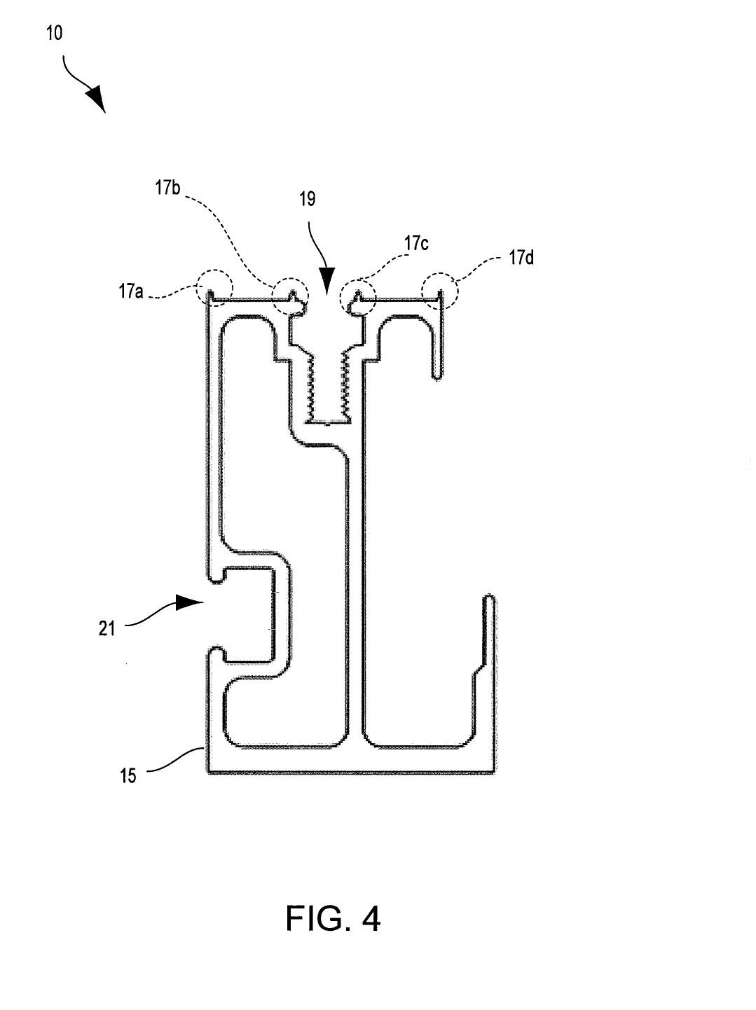

Because of variations inherent in roofs and other surfaces on which the embodiment racking systems may installed, in order to ensure that panels are appropriately secured to the rail and maintain grounding, even in the face of uneven roof surfaces, an embodiment rail may be configured with any number of integrated grounding bars. FIG. 4 illustrates another embodiment mounting rail 15 that is configured with four grounding bars 17a, 17b, 17c and 17d, a top attachment slot 19, and a side attachment slot 21. Rails of racking systems according to the various embodiments may be configured with any suitable number of grounding bars, which may be less than or greater than four, in order to achieve optimum grounding of the photovoltaic panels given a specific surface or structure. It should be noted that while the grounding bars 17a-d are integrated or cast into the mounting rail 15, this is not meant as a limitation. For example, the grounding bars may also be applied, welded or otherwise secured by methods known in the art, after the mounting rail is cast, so long as those grounding bars provide a grounding path from the bar to the rail and possess a piercing feature that permits the grounding bars to pierce the anodized layer thereby allowing the photovoltaic panel frame to be grounded.

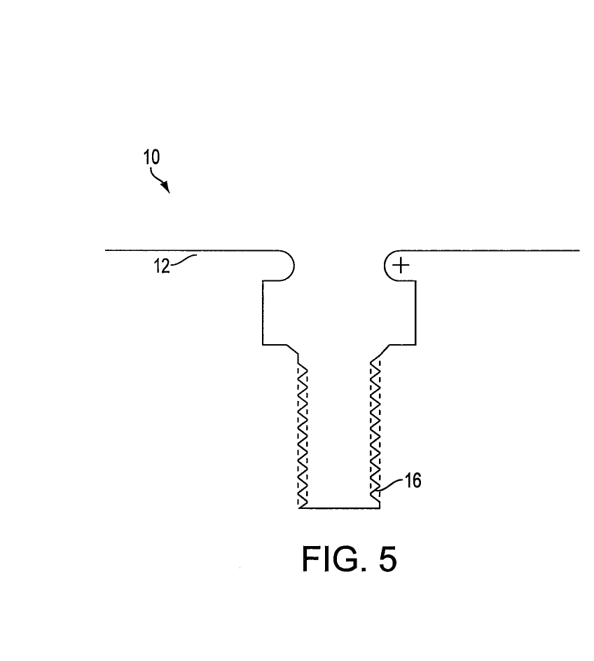

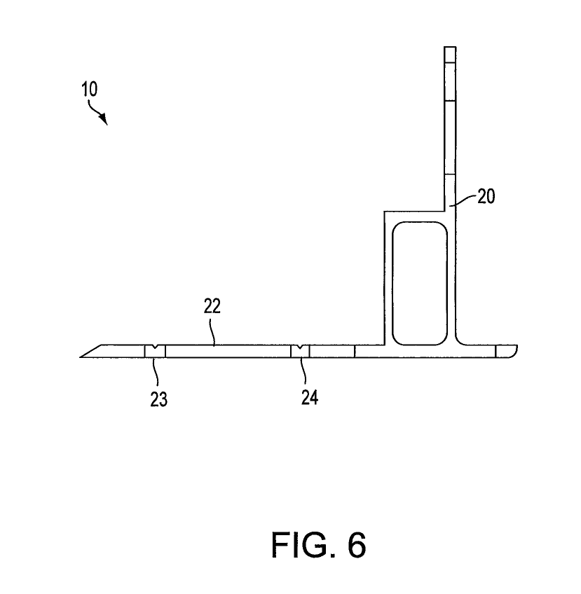

FIG. 5 illustrates an attachment slot 16 (e.g., slide-in bolt, screw boss, etc.) as part of an extruded rail 12 in racking system 10. The attachment slot 16 may be configured to secure a mounting bracket, shown in FIG. 6 below. While the attachment slot is shown as a threaded slot, this is merely an example configuration and is not intended to limit the attachment slot to a particular shape.

FIG. 6 illustrates a mounting bracket 20 in racking system 10. Mounting brackets 20 may be attached to the roof in equal intervals, and may be configured to secure an extruded rail 12. Base portion 22 of bracket 20 is secured to a roof under shingles, as an example. Fasters may be placed through channels 23, 24 to allow bracket 20 to be secured to a roof or other structure.

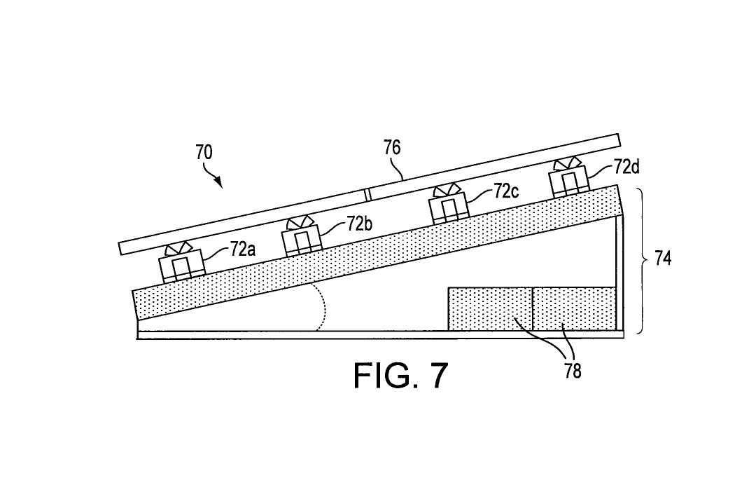

FIG. 7 illustrates a ballast mount frame with integrated grounding bar rails for mounting a solar panel racking system 70. Rails 72a, 72b, 72c, 72d may be secured to a ballast mount frame 74, according to an embodiment. Photovoltaic panels 76 may be secured to the rails 72a-d and the integrated grounding bars may perforate the anodized frames of the panels 76. Ballasts 78 are used to provide added weight and to stabilize ballast mount frame 74. As illustrated, the photovoltaic panels are secured to the ballast mount at an angle.

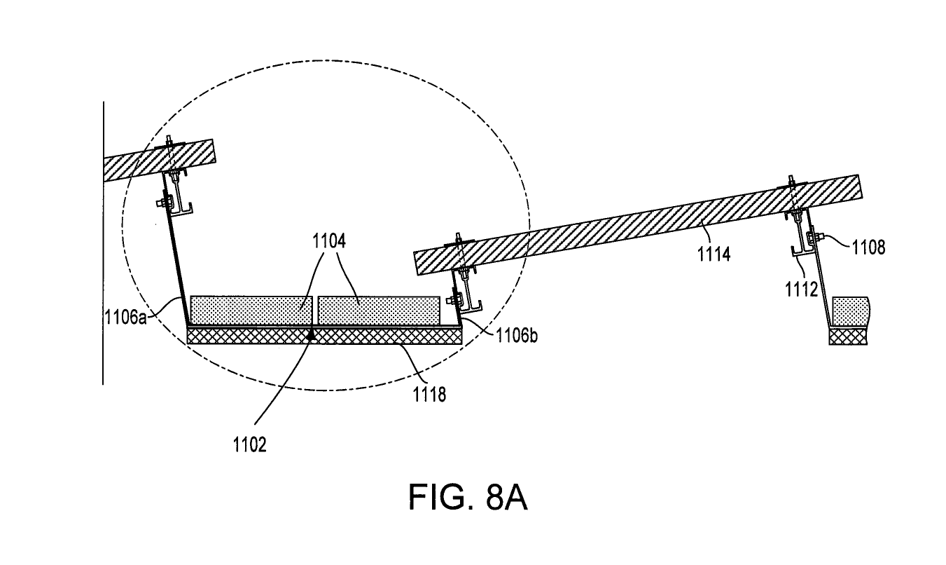

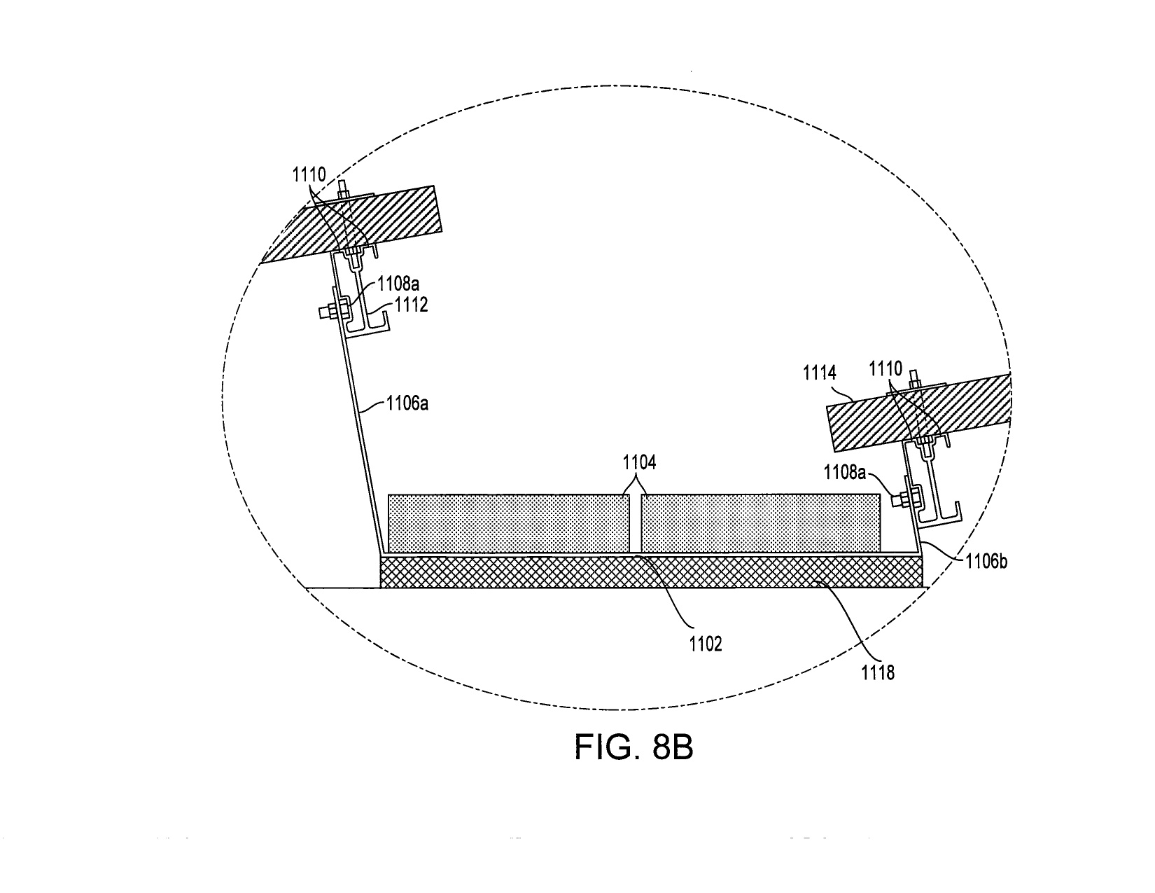

FIGS. 8A and 8B illustrate the use of ballast pans in a ballast mounted system, according to an embodiment. As discussed with respect to the embodiments illustrated above, an integrated rail 1112 includes grounding bars 1110. The ballast pans 1102 may each hold up to six ballast blocks 1104 laid flat (e.g., like floor tiles), or up to twelve ballast blocks 1104 if placed on their sides or stacked. The grounding and orientation of ballast blocks is not meant as a limitation. Other ballast pan sizes and block sizes and materials will dictate actual grounding and block placement. In a preferred embodiment, each ballast pan 1102 may be a flat, substantially horizontal piece of galvanized steel or aluminum with two bent substantially vertical portions 1106a, 1106b. The flat piece of galvanized steel or aluminum may form an intermediate portion to which the substantially vertical portions 1106a, 1106b attach. The face of an integrated rail 1112 may be bolted to the substantially vertical portions 1106a, 1106b using bolts 1108a, 1108b. The substantially vertical portions 1106a, 1106b also may partially deflect wind to help counteract wind uplift. Further, substantially vertical portion 1106a may be offset in length (i.e., different height) from substantially vertical portion 1106b to provide a tilt angle for the photovoltaic panels 1114, which varies according to the degree of offset. The substantially vertical portions 1106a, 1106b may intersect with a photovoltaic panel 1114 at an angle of approximately 90 degrees, as shown, and may be at an offset (e.g., oblique) angle to the roof 1118. In an alternative configuration (not shown), the substantially vertical portions 1106a, 1106b may be at an angle of approximately 90 degrees to the roof 1118, and intersect the photovoltaic panel 1114 at an offset angle. Either case depends on positioning the photovoltaic panel 1114 at the optimum angle required for maximizing absorption of solar energy. The length of the ballast pan, in conjunction with the adjustable tilt angle, also prevents the rows of photovoltaic panels from casting shade over one another. In addition, the integrated rails 1112 may be configured to easily hold a ground wire, for example, by including a wire raceway inlaid in the integrated rails 1112.

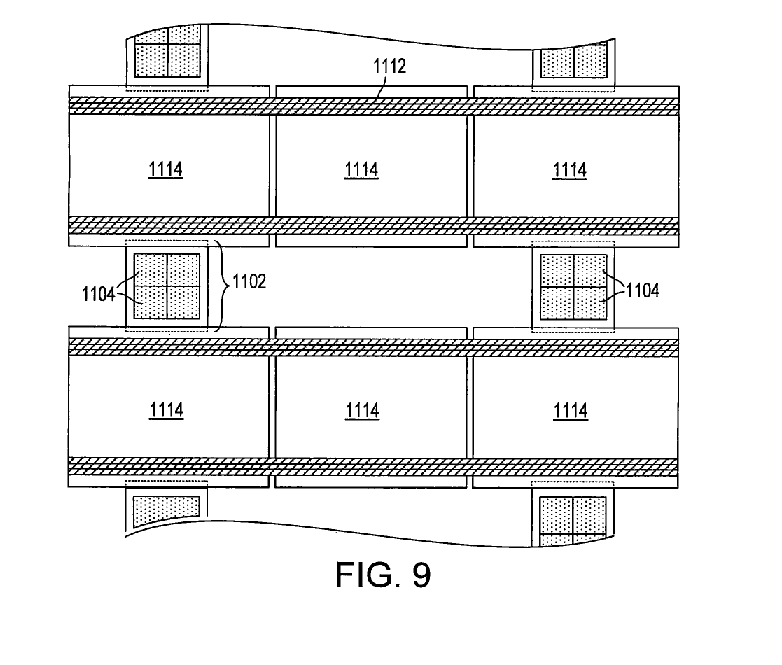

FIG. 9 illustrates a top view of a ballast mounted system. In a preferred embodiment, the ballast pans 1102 function to form electrical connections between adjacent rows of photovoltaic panels 1114. By configuring the array with ballast pans 1102 and integrated rails 1112 in this manner, the entire layout of the ballast mounted system may require only a single ground wire from the entire array to the equipment room. That is, when connected through a ground wire, a rail carries the grounding to each panel in a row, and the ballast pans carry the grounding to each adjacent row in the system. This also enhances the safety of the system.

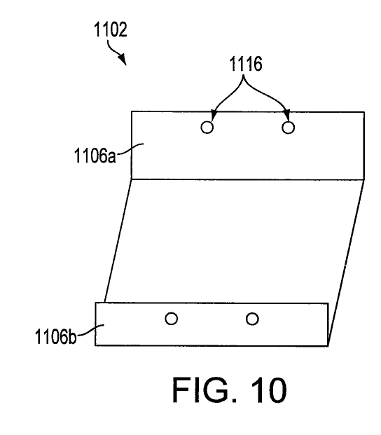

FIG. 10 illustrates a ballast pan 1102 with mounting holes 1116, according to various embodiments. These mounting holes 1108 may be configured to accept the attachment of grounding bar rails. In a preferred embodiment, the rails may be directly bolted to the ballast pans 1102. For example, each ballast pan may have four mounting holes that are pre-drilled to fit ⅜″ bolts.

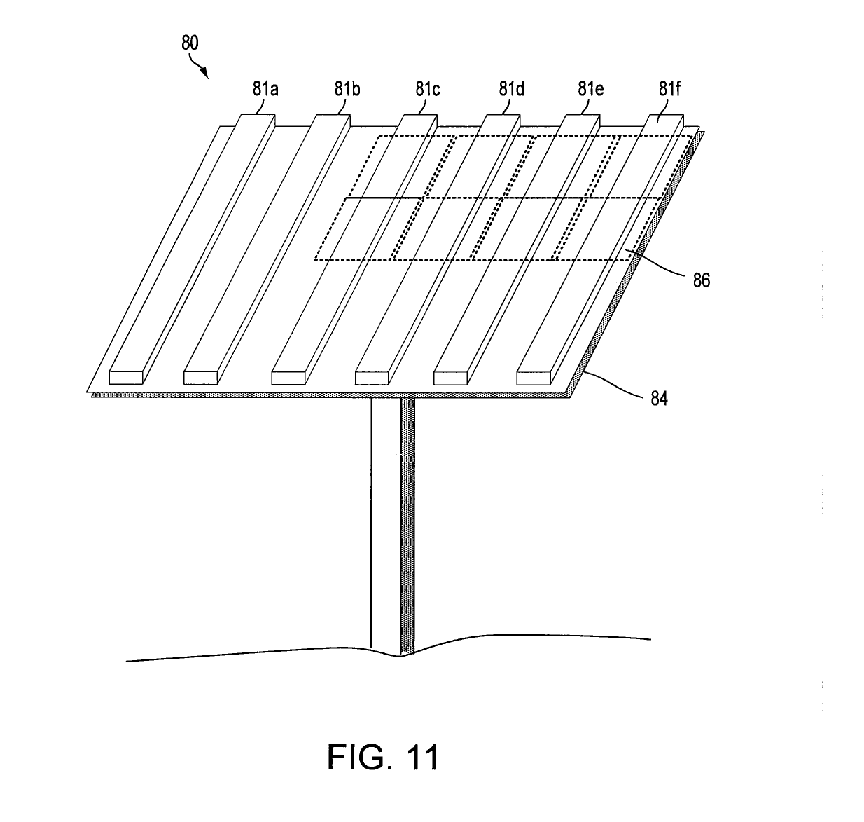

FIG. 11 illustrates integrated grounding bar rails adapted in a pole mount support photovoltaic racking system 80. In an embodiment, rails 81a, 81b, 81c, 81d, 81e, 81f may be secured to a canopy support frame 82. Photovoltaic panels 86 may be secured to the rails 81a-f and the grounding bars on the rails may perforate the anodized frames of the panels 86.

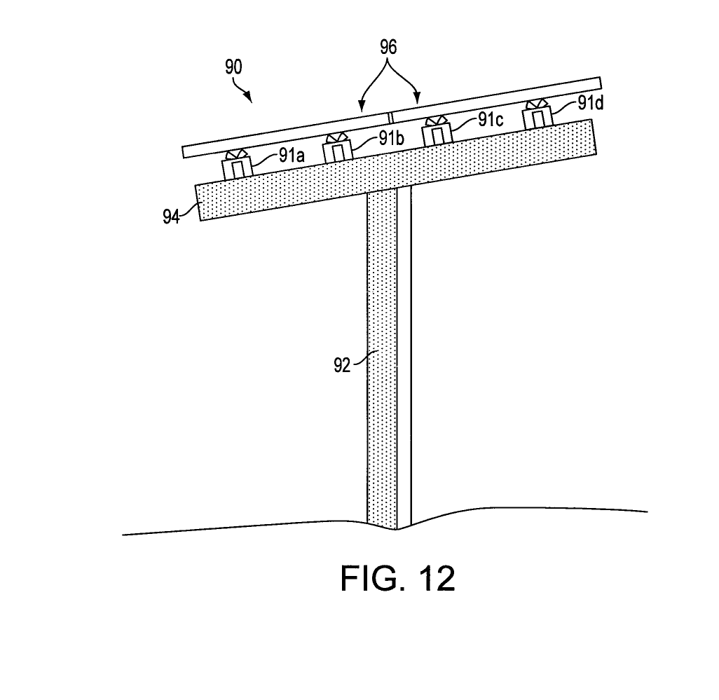

FIG. 12 illustrates integrated grounding bar rails adapted in a pole mount photovoltaic racking system 90. In an embodiment, rails 91a, 91b, 91c, 91d may be secured to a pole rail mount frame 94. The pole rail mount frame 94 may be secured to pole mount 92 in the ground. Photovoltaic panels 96 may be secured to the rails 91a-d and the integrated ground bars may perforate the anodized frames of the panels 96.

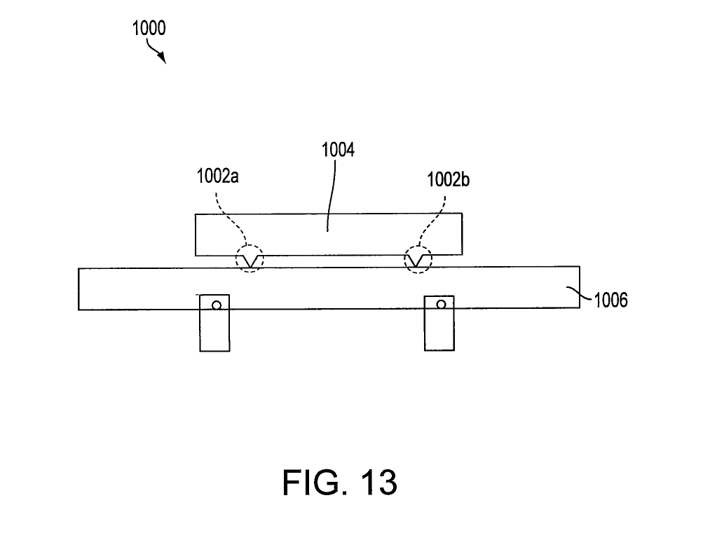

In an alternative embodiment photovoltaic racking system, one or more grounding bars may be integrated in the frames of the photovoltaic panels. FIG. 13 illustrates an installed photovoltaic panel frame 1004 configured with integrated grounding bars 1002a, 1002b. Grounding bars 1002a, 1002b may perforate a mounting rail 1006 of a racking system 1000 when the frame 1004 is secured to the mounting rail 1006. It should be noted that while the grounding bars 1002a, 1002b are integrated or cast into the photovoltaic panel frame 1004, this is not meant as a limitation. For example, the grounding bars may also be applied, welded or otherwise secured by methods known in the art, after the photovoltaic panel frame is manufactured, so long as those grounding bars provide a grounding path from the bars to the frame and possess a piercing feature that permits the grounding bars to pierce the mounting rail 1006, thereby allowing the photovoltaic panel frame to be grounded.

The various embodiment integrated grounding bar rails and frames require no special tools for installation. The various embodiments eliminate the problems associated with grounding clips that can move around during installation and not properly ground the panels to the rails. Further, the various embodiments may be used for installation of solar panels regardless of the type of mounting configuration. This includes roof mounted systems, for example, both penetrating and non-penetrating or ballasted, ground mounted systems, pole mounted systems, canopies and carports, etc. The various embodiments and associated grounding bars illustrated herein are universally adaptable to all brands and sizes of solar panels.

The embodiments described above may be implemented on any of a variety of roof types, including, but not limited to, cross-gabled, hipped, mansard, flat, or shed roofs. Further, the various embodiments may be implemented on other flat surfaces, including, but not limited to, a field in a photovoltaic farm, a parking lot, etc. The foregoing method descriptions and process diagram are provided merely as illustrative examples and are not intended to require or imply that the processes of the various embodiments must be performed in the order presented. Skilled artisans may implement the described functionality in varying ways for each particular roofing system, but such implementation decisions should not be interpreted as causing a departure from the scope of the present invention. Words such as “thereafter,” “then,” “next,” etc. are not intended to limit the order of the processes; these words are simply used to guide the reader through the description of the methods. Further, any reference to claim elements in the singular, for example, using the articles “a,” “an” or “the” is not to be construed as limiting the element to the singular.

The foregoing description of the various embodiments is provided to enable any person skilled in the art to make or use the present invention. Various modifications to these embodiments will be readily apparent to those skilled in the art, and the generic principles defined herein may be applied to other embodiments without departing from the scope of the invention. Thus, the present invention is not intended to be limited to the embodiments shown herein, and instead the claims should be accorded the widest scope consistent with the principles and novel features disclosed herein. Further, the Abstract that appears in this application is simply a summary of the various embodiments, and is not meant to limit the claims.

What is claimed is:

1. A method of grounding a photovoltaic system, comprising:
attaching at least one photovoltaic panel to at least one mounting rail, wherein the at least one mounting rail is configured with multiple integrated grounding bars;
tightening the at least one photovoltaic panel to the at least one mounting rail with mounting clips, wherein the multiple integrated grounding bars perforate an anodized coating of the at least one photovoltaic panel; and
connecting a grounding wire to the at least one mounting rail, wherein the grounding wire connects to an end of each mounting rail.

2. The method of claim 1, wherein the at least one mounting rail configured with multiple integrated grounding bars comprises at least one mounting rail configured with at least two integrated grounding bars.

3. The method of claim 1, wherein the at least one mounting rail configured with multiple integrated grounding bars comprises at least one mounting rail configured with at least three integrated grounding bars.

4. The method of claim 1, wherein the at least one mounting rail configured with multiple integrated grounding bars comprises at least one mounting rail configured with at least four integrated grounding bars.

5. A method of grounding a photovoltaic system, comprising:
attaching a first set of photovoltaic panels to a first mounting rail having multiple grounding bars;
attaching a second set of photovoltaic panels to a second mounting rail having multiple grounding bars;
tightening the first and second sets of photovoltaic panels to the first and second mounting rails with mounting clips, wherein the multiple grounding bars perforate anodized coatings of the photovoltaic panels;
securing the photovoltaic system to a surface using a ballast pan, wherein the ballast pan is configured to hold a plurality of ballast blocks, and wherein the ballast pan comprises a first substantially vertical portion and a second substantially vertical portion;
attaching the first mounting rail to the first substantially vertical portion; and
attaching the second mounting rail to the second substantially vertical portion.

6. The method of claim 5, wherein the multiple grounding bars comprises at least two grounding bars.

7. The method of claim 5, wherein the multiple grounding bars comprises three grounding bars.

8. The method of claim 5, wherein the multiple grounding bars comprises four grounding bars.

9. A grounding system for photovoltaic panels, the photovoltaic panels having anodized frame surfaces, comprising:
a mounting rail comprising multiple integrated grounding bars; and
mounting clips configured to tighten the photovoltaic panels to the mounting rail,
wherein the multiple integrated grounding bars perforate anodized aluminum frame surfaces of the photovoltaic panels.

10. The grounding system of claim 9, wherein the mounting rail comprises at least two integrated grounding bars.

11. The grounding system of claim 9, wherein the mounting rail comprises at least three integrated grounding bars.

12. The grounding system of claim 9, wherein the mounting rail comprises at least four integrated grounding bars.

13. A method of grounding a photovoltaic system, comprising:
attaching at least one photovoltaic panel frame to at least one mounting rail, wherein the at least one photovoltaic panel frame is configured with a plurality of integrated grounding bars;
tightening the photovoltaic panel frame to the at least one mounting rail with mounting clips, wherein the plurality of integrated grounding bars perforate a surface of the mounting rail; and
connecting a grounding wire to the at least one mounting rail, wherein the grounding wire connects to an end of each mounting rail.

14. The method of claim 13, wherein the plurality of integrated grounding bars comprises at least two integrated grounding bars.

15. The method of claim 13, wherein the plurality of integrated grounding bars comprises at least three integrated grounding bars.

16. The method of claim 13, wherein the plurality of integrated grounding bars comprises at least four integrated grounding bars.

17. A method of grounding a photovoltaic system, comprising:
providing at least one mounting rail created in an initial manufacturing process;
attaching multiple grounding bars to the at least one mounting rail after the initial manufacturing process;
attaching at least one photovoltaic panel to the at least one mounting rail, wherein the at least one mounting rail is configured with the attached multiple grounding bars;
tightening the at least one photovoltaic panel to the at least one mounting rail with mounting clips, wherein the multiple integrated grounding bars perforate an anodized coating of the at least one photovoltaic panel; and
connecting a grounding wire to the at least one mounting rail, wherein the grounding wire connects to an end of each mounting rail.

18. A method of grounding a photovoltaic system, comprising:
providing at least one photovoltaic panel frame created in an initial manufacturing process;
attaching multiple grounding bars to the at least one photovoltaic panel frame after the initial manufacturing process;
attaching at the least one photovoltaic panel frame to at least one mounting rail, wherein the at least one photovoltaic panel frame is configured with the attached multiple grounding bars;
tightening the photovoltaic panel frame to the at least one mounting rail with mounting clips, wherein the attached multiple grounding bars perforate a surface of the mounting rail; and
connecting a grounding wire to the at least one mounting rail, wherein the grounding wire connects to an end of each mounting rail.
